(19) United States
(12) Patent Application Publication
(10) Pub. No.: US 2026/0324294 A1
(43) Pub. Date: Oct. 15, 2026

(54) EMBEDDING TALL MRAM DEVICE IN BEOL INTERCONNECT STRUCTURE

(71) Applicant: INTERNATIONAL BUSINESS MACHINES CORPORATION, Armonk, NY (US)

(72) Inventors: Ashim Dutta, Clifton Park, NY (US); Kamal Rudra, Albany, NY (US); Chih-Chao Yang, Glenmont, NY (US)

(21) Appl. No.: 19/173,884

(22) Filed: Apr. 9, 2025

(51) Int. Cl. H10N 50/80; H10N 50/01; H10N 50/10

(52) U.S. Cl. CPC H10N 50/80; H10N 50/01; H10N 50/10

(57) ABSTRACT

Embodiments of present invention provide a semiconductor structure. The structure includes a magnetoresistive random-access memory structure having a magnetic tunnel junction pillar; a top electrode; and a bottom electrode; a bottom electrode contact in contact with a bottom surface of the bottom electrode; and a back-end-of-line interconnect structure having a first and a second metal levels with each metal level including one or more metal lines and one or more top vias, where a top surface of the top electrode is coplanar with top surfaces of the one or more top vias of the second metal level, and a bottom surface of the bottom electrode contact is coplanar with bottom surfaces of the one or more top vias of the first metal level.

### BACKGROUND

The present application relates to manufacturing of semiconductor integrated circuits. More particularly, it relates to embedding tall MRAM device in BEOL interconnect structure and the structure formed thereby.

In a conventional process of forming embedded magnetoresistive random-access memory (MRAM) device, significant gouging of dielectric material below the level of bottom electrode occurs during an etch process of the magnetic tunnel junction (MTJ) stack. Due to pre-determined and usually limited distance between two adjacent metal levels in the interconnect structure, this gouging activity may consequently remove most of the dielectric cap layer in both memory and logic areas, exposing metal lines in the interconnect metal level below, therefore become a significant concern for the MTJ stack and downstream processes. This gouging problem becomes worse as MRAM pillar pitch shrinks.

### SUMMARY

Embodiments of present invention provide a semiconductor structure. The semiconductor structure includes a magnetoresistive random-access memory (MRAM) structure having a magnetic tunnel junction (MTJ) pillar; a top electrode at a top surface of the MTJ pillar; and a bottom electrode at a bottom surface of the MTJ pillar; a bottom electrode contact in contact with a bottom surface of the bottom electrode; and a back-end-of-line interconnect structure having at least a first and a second metal levels with each metal level including one or more metal lines and one or more top vias, the one or more top vias of the first metal level connecting the one or more metal lines of the first metal level to the one or more metal lines of the second metal level, where a top surface of the top electrode is coplanar with top surfaces of the one or more top vias of the second metal level, and a bottom surface of the bottom electrode contact is coplanar with bottom surfaces of the one or more top vias of the first metal level.

In one embodiment, a bottom surface of the bottom electrode is coplanar with bottom surfaces of the one or more metal lines of the second metal level.

In another embodiment, the bottom electrode contact is directly on top of a metal line of the first metal level and has a width that is narrower than a width of the metal line of the first metal level.

In yet another embodiment, the MRAM structure and the interconnect structure are formed on top of a dielectric layer, and a conductive via embedded in the dielectric layer connects the MRAM structure, via the metal line of the first metal level, to an active device underneath the dielectric layer.

According to one embodiment, the semiconductor structure further includes an encapsulating layer surrounding sidewalls of the MTJ pillar, wherein the encapsulating layer extends below a bottom surface of the bottom electrode to horizontally surround at least a portion of the bottom electrode contact.

According to another embodiment, the semiconductor structure further includes a third metal level having one or more metal lines, wherein one of the one or more metal lines of the third metal level is a top electrode contact in contact with a top surface of the top electrode of the MRAM structure.

In one embodiment, the bottom electrode contact has a height that is higher than a height of the one or more top vias of the first metal level.

In another embodiment, a combined height of the bottom electrode contact and the MRAM structure equals to a combined height of the one or more top vias of the first metal level, the one or more metal lines of the second metal level, and the one or more top vias of the second metal level.

Embodiments of present invention further provide a method of forming a semiconductor structure. The method includes forming a first metal level with a first set of metal layers; patterning the first set of metal layers into one or more top vias and one or more metal lines of the first metal level and into a bottom electrode contact; forming a magnetoresistive random-access memory (MRAM) structure on top of the bottom electrode contact, the MRAM structure having a magnetic tunnel junction (MTJ) pillar, a top electrode above the MTJ pillar, and a bottom electrode below the MTJ pillar; forming a second metal level with a second set of metal layers on top of the one or more top vias of the first metal level; patterning the second set of metal layers into one or more top vias and one or more metal lines of the second metal level, with top surfaces of the one or more top vias of the second metal level being coplanar with a top surface of the top electrode; and forming a top electrode contact on top of the top electrode.

According to one embodiment, the method further includes embedding the one or more top vias of the first metal level in a dielectric layer; depositing a bottom electrode layer on top of the one or more top vias of the first metal level and the dielectric layer; depositing an MTJ stack on top of the bottom electrode layer; and depositing a top electrode layer on top of the MTJ stack.

According to another embodiment, the method further includes patterning the top electrode layer, the MTJ stack, and the bottom electrode layer into the top electrode, the MTJ pillar, and the bottom electrode in a selective etch process, the selective etch process creates gouges in the dielectric layer between the one or more top vias of the first metal level.

According to yet another embodiment, the method further includes forming an encapsulating layer surrounding sidewalls of the MTJ pillar, the encapsulating layer having a material different from that of the dielectric layer.

In one embodiment, patterning the first set of metal layers into the bottom electrode contact includes etching one of the metal layers into a bottom electrode contact on top of a metal line of the first metal level, the bottom electrode contact having a width narrower than a width of the metal line of the first metal level.

In another embodiment, patterning the first set of metal layers includes etching the first set of metal layers in a subtractive patterning process.

In yet another embodiment, forming the top electrode contact on top of the top electrode includes forming one or more metal lines of a third metal level on top of the one or more top vias of the second metal level and on top of the top electrode of the MRAM structure.

### BRIEF DESCRIPTION OF THE DRAWINGS

The present invention will be understood and appreciated more fully from the following detailed description of embodiments of present invention, taken in conjunction with accompanying drawings of which:

FIG. 1 is a demonstrative illustration of cross-sectional view of a semiconductor structure at a step of manufacturing thereof according to one embodiment of present invention;

FIG. 2 is a demonstrative illustration of cross-sectional view of a semiconductor structure at a step of manufacturing thereof, following the step illustrated in FIG. 1, according to one embodiment of present invention;

FIG. 3 is a demonstrative illustration of cross-sectional view of a semiconductor structure at a step of manufacturing thereof, following the step illustrated in FIG. 2, according to one embodiment of present invention;

FIG. 4 is a demonstrative illustration of cross-sectional view of a semiconductor structure at a step of manufacturing thereof, following the step illustrated in FIG. 3, according to one embodiment of present invention;

FIG. 5 is a demonstrative illustration of cross-sectional view of a semiconductor structure at a step of manufacturing thereof, following the step illustrated in FIG. 4, according to one embodiment of present invention;

FIG. 6 is a demonstrative illustration of cross-sectional view of a semiconductor structure at a step of manufacturing thereof, following the step illustrated in FIG. 5, according to one embodiment of present invention;

FIG. 7 is a demonstrative illustration of cross-sectional view of a semiconductor structure at a step of manufacturing thereof, following the step illustrated in FIG. 6, according to one embodiment of present invention;

FIG. 8 is a demonstrative illustration of cross-sectional view of a semiconductor structure at a step of manufacturing thereof, following the step illustrated in FIG. 7, according to one embodiment of present invention;

FIG. 9 is a demonstrative illustration of cross-sectional view of a semiconductor structure at a step of manufacturing thereof, following the step illustrated in FIG. 8, according to one embodiment of present invention;

FIG. 10 is a demonstrative illustration of cross-sectional view of a semiconductor structure at a step of manufacturing thereof, following the step illustrated in FIG. 9, according to one embodiment of present invention;

FIG. 11 is a demonstrative illustration of cross-sectional view of a semiconductor structure at a step of manufacturing thereof, following the step illustrated in FIG. 10, according to one embodiment of present invention;

FIG. 12 is a demonstrative illustration of cross-sectional view of a semiconductor structure at a step of manufacturing thereof, following the step illustrated in FIG. 11, according to one embodiment of present invention;

FIG. 13 is a demonstrative illustration of cross-sectional view of a semiconductor structure at a step of manufacturing thereof, following the step illustrated in FIG. 12, according to one embodiment of present invention;

FIG. 14 is a demonstrative illustration of cross-sectional view of a semiconductor structure at a step of manufacturing thereof, following the step illustrated in FIG. 13, according to one embodiment of present invention;

FIG. 15 is a demonstrative illustration of cross-sectional view of a semiconductor structure at a step of manufacturing thereof, following the step illustrated in FIG. 14, according to one embodiment of present invention;

FIG. 16 is a demonstrative illustration of cross-sectional view of a semiconductor structure at a step of manufacturing thereof, following the step illustrated in FIG. 15, according to one embodiment of present invention; and

FIG. 17 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms "about" or "substantially" as used herein with regard to thicknesses, widths, percentages, ranges, etc., are meant to denote being close or approximate to, but not exactly. For example, the term "about" or "substantially" as used herein implies that a small margin of error may be present such as, by way of example only, 1% or less than the stated amount. Likewise, the terms "on", “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

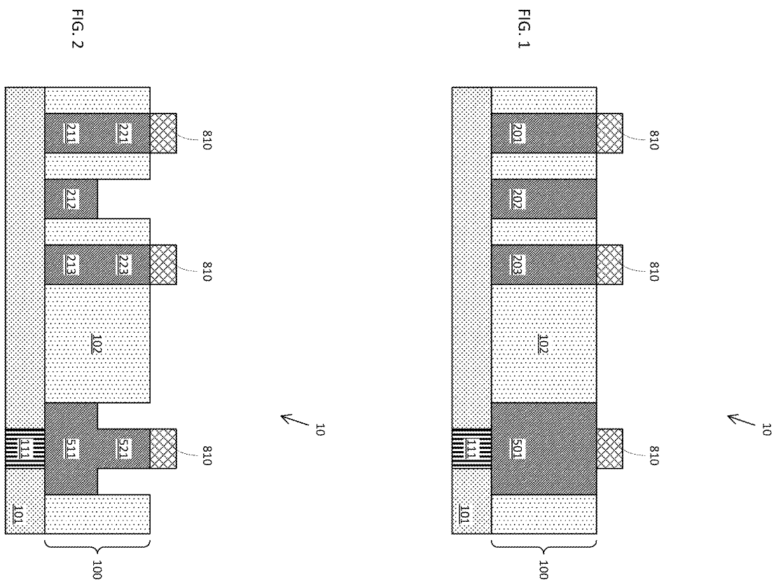

FIG. 1 is a demonstrative illustration of cross-sectional view of a semiconductor structure 10 in a step of manufacturing thereof according to one embodiment of present invention. More specifically, embodiments of present invention provide receiving, providing, or creating the semiconductor structure 10 as is illustrated in FIG. 1. The semiconductor structure 10 includes a supporting structure 101 or supporting element on top of one or more active devices such as, for example, field-effect-transistors (now shown). The supporting structure 101 may be a layer of dielectric material, such as silicon-oxide (SiOx) or silicon-nitride (SiN), with one or more conductive vias formed or embedded therein, such as a conductive via 111. In one embodiment, the conductive via 111 may be connected to one of the one or more active devices underneath thereof.

Embodiments of present invention further provide forming a first metal level 100 by first creating a first set of metal layers in a dielectric layer 102 such as a layer of SiOx. The first set of metal layers may include, for example, metal layers 201, 202, 203, and 501 which may be made of, for example, copper (Cu), tungsten (W), cobalt (Co) or other suitable conductive materials. Embodiments of present invention further provide forming the first metal level 100 through a subtractive patterning process. In doing so, hard masks 810 may be formed covering some of the first set of metal layers such as covering metal layers 201, 203, and 501. It is noted here that the hard masks 810 cover only a portion or portions of the metal layers 201, 203, and 501 in a direction into and out of the drawing. In one embodiment, as is illustrated in FIG. 1, a width of the hard mask 810 on top of the metal layer 501 may be narrower than a width of the metal layer 501.

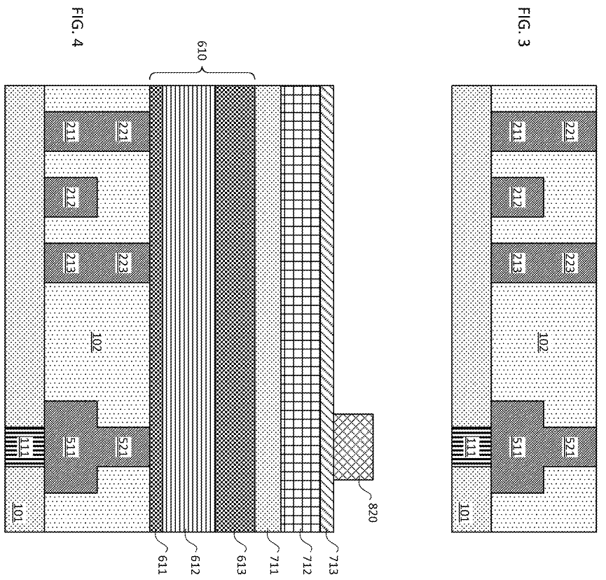

FIG. 2 is a demonstrative illustration of cross-sectional view of the semiconductor structure 10 at a step of manufacturing thereof, following the step illustrated in FIG. 1, according to one embodiment of present invention. More specifically, embodiments of present invention provide performing a subtractive patterning process to remove portions of the first set of metal layers of the metal layers 201, 202, 203, and 501 that are not covered by the hard masks 810. The subtractive patterning process may be a selective etch process that results in, for example, one or more top vias 221, 223, and 521 of the first metal level 100 on top of one or more metal lines 211, 212, 213, and 511 of the first metal level 100. It is noted here that portions of the metal layers 201, 203, and 205 that are covered by the hard masks 810, and thus not etched, are patterned into the top vias 221, 223, and 521. As is described below in more details, the top via 521 may serve or work as a bottom electrode contact of a MRAM structure to be formed thereupon and hereafter may be referred to as a bottom electrode contact 521 hereinafter. A bottom surface of the bottom electrode contact 521 may be substantially coplanar with bottom surfaces of the top vias 221 and 223 of the first metal level 100.

FIG. 3 is a demonstrative illustration of cross-sectional view of the semiconductor structure 10 at a step of manufacturing thereof, following the step illustrated in FIG. 2, according to one embodiment of present invention. More specifically, embodiments of present invention provide depositing a dielectric material into the openings or recesses, created by the subtractive patterning process of the first metal level 100, above the one or more metal lines 211, 212, 213 and 511 and surrounding the one or more top vias 221 and 223, and the bottom electrode contact 521 to form a dielectric layer 102. A chemical-mechanical-polishing (CMP) process may next be applied to planarize a top surface of the dielectric layer 102 until top surfaces of the one or more top vias 221 and 223, and the bottom electrode contact 521 are exposed. In other words, the one or more top vias 221 and 223, and the bottom electrode contact 521 may be embedded in the dielectric layer 102. In one embodiment, the hard masks 810 may be removed before depositing the dielectric material to fill the openings or recesses.

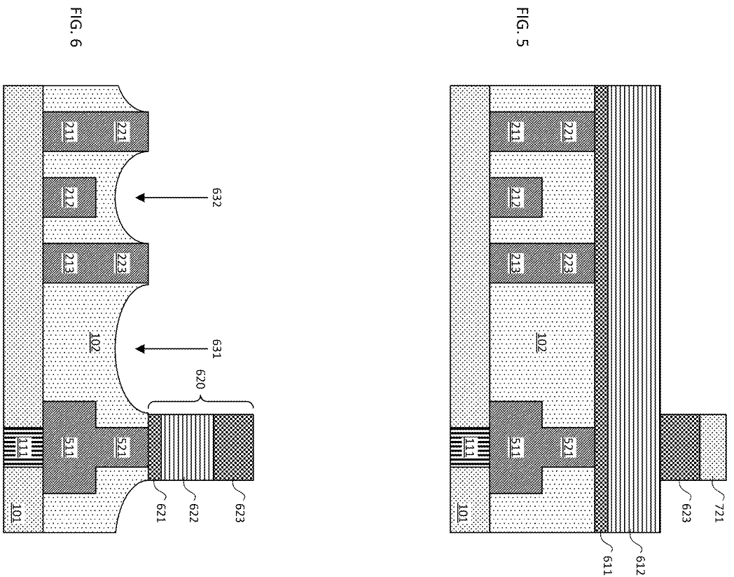

FIG. 4 is a demonstrative illustration of cross-sectional view of the semiconductor structure 10 at a step of manufacturing thereof, following the step illustrated in FIG. 3, according to one embodiment of present invention. More specifically, embodiments of present invention provide forming a bottom electrode layer 611 on top of the dielectric layer 102; forming an MTJ stack 612 on top of the bottom electrode layer 611; and forming a top electrode layer 613 on top of the MTJ stack 612, thereby forming an MRAM stack 610 on top of and in contact with the bottom electrode contact 521.

In one embodiment, the bottom electrode layer 611 and/or the top electrode layer 613 may be made of, for example, titanium (Ti), titanium-nitride (TiN), tantalum (Ta), tantalum-nitride (TaN), tungsten (W), or other suitable conductive materials. The MTJ stack 612 may usually include, for example, a first ferromagnetic layer, a tunnel barrier (TB) layer, and a second ferromagnetic layer. One of the first and second ferromagnetic layers may be, for example, a reference layer and the other may be a free layer.

Embodiments of present invention may further include patterning the MRAM stack 610 into an MRAM structure. In doing so, embodiments of present invention first provide forming a stack of mask layers on top of the MRAM stack 610. For example, an oxide layer 711 may be deposited on top of the top electrode layer 613, an organic planarization (OPL) layer 712 may be formed on top of the oxide layer 711, and a silicon-based anti-reflective coating (SiARC) layer 713 may be formed on top of the OPL layer 712.

The formation of the bottom electrode layer 611, the MTJ stack 612, the top electrode layer 613, the oxide layer 711, the OPL layer 712, and the SiARC layer 713 may be made through, for example, a deposition process such as an atomic-layer-deposition (ALD) process, a chemical-vapor-deposition (CVD) process, a physical-vapor-deposition (PVD) process, or made by any other currently existing or future developed processes.

Following the formation of the multi-layer mask layer, a photo-resist mask 820 may be formed on top of the stack of mask layer through a lithographic patterning process. The photo-resist mask 820 may represent a shape of the MRAM structure to be formed, such as may have a circular shape from a top view thereof, although other shapes of form are fully contemplated here as well.

FIG. 5 is a demonstrative illustration of cross-sectional view of the semiconductor structure 10 at a step of manufacturing thereof, following the step illustrated in FIG. 4, according to one embodiment of present invention. More specifically, embodiments of present invention provide transferring the pattern of the photo-resist mask 820 onto to the oxide layer 711, through selectively etching the SiARC layer 713, the OPL layer 712, and the oxide layer 711 with the photo-resist mask 820 covering a portion thereof, thereby forming a hard mask 721. Next, the hard mask 721 may be used in a selective etch process in patterning the MRAM stack 610 into an MRAM structure. For example, according to one embodiment, the hard mask 721 may initially be used in a selective etch process in patterning the top electrode layer 613 into a top electrode 623.

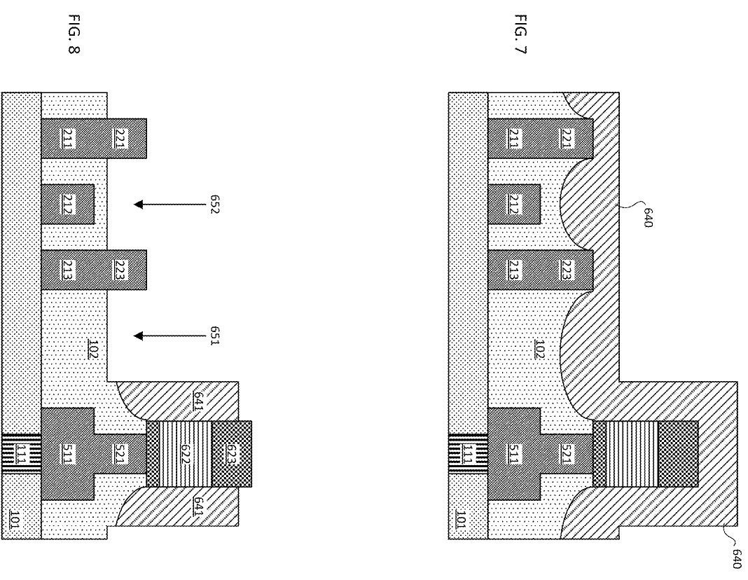

FIG. 6 is a demonstrative illustration of cross-sectional view of the semiconductor structure 10 at a step of manufacturing thereof, following the step illustrated in FIG. 5, according to one embodiment of present invention. More specifically, embodiments of present invention provide performing a selective etch process, such as an ion-beam-etch (IBE) process, to further etch the MTJ stack 612 and the bottom electrode layer 611, thereby creating a MRAM structure 620 that includes a bottom electrode 621, a MTJ pillar 622 on top of the bottom electrode 621, and a top electrode 623 on top of the MTJ pillar 622. In other words, the MRAM structure 620 includes a top electrode 623 on a top surface of the MTJ pillar 622, and a bottom electrode 621 at a bottom surface of the MTJ pillar 622. The bottom electrode contact 521 is in contact with a bottom surface of the bottom electrode 621, and the conductive via 111 connects the MRAM structure 620 with an active device underneath the supporting structure 101 via the bottom electrode contact 521 and the metal line 511 of the first metal level 100.

The selective etch process, such as the IBE process, may cause significant gouging into the dielectric layer 102 that are at a level below a bottom surface of the MRAM structure 620. For example, the IBE process may create a gouge 631 between the top via 223 and the bottom electrode contact 521 and a gouge 632 between the top via 221 and the top via 223. However, according to embodiment of present invention, because of the raised height of the MRAM structure 620 by the bottom electrode contact 521, which is formed from one of the top vias of the first metal level 100 and thus has a full height of the one or more top vias 221 and 223, the resulting gouges 631 and 632 may not be deep enough to cause exposure of the one or more metal lines 211, 212 and 213 of the first metal level 100.

FIG. 7 is a demonstrative illustration of cross-sectional view of the semiconductor structure 10 at a step of manufacturing thereof, following the step illustrated in FIG. 6, according to one embodiment of present invention. More specifically, embodiments of present invention provide encapsulating the MRAM structure 620, in particular the MTJ pillar 622, to help protect subsequently formed dielectric materials surrounding the MRAM structure 620 from being, for example, contaminated. In doing so, a layer of encapsulation material 640 may be deposited onto the MRAM structure 620, the exposed dielectric layer 102, and the exposed top surfaces of the one or more top vias 221 and 223. The layer of encapsulation material 640 may be formed substantially conformally and may be made of, for example, silicon-nitride (SiN), silicon-carbonitride (SiCN), hydrogen doped silicon-carbonitride (SiCNH), or other suitable materials.

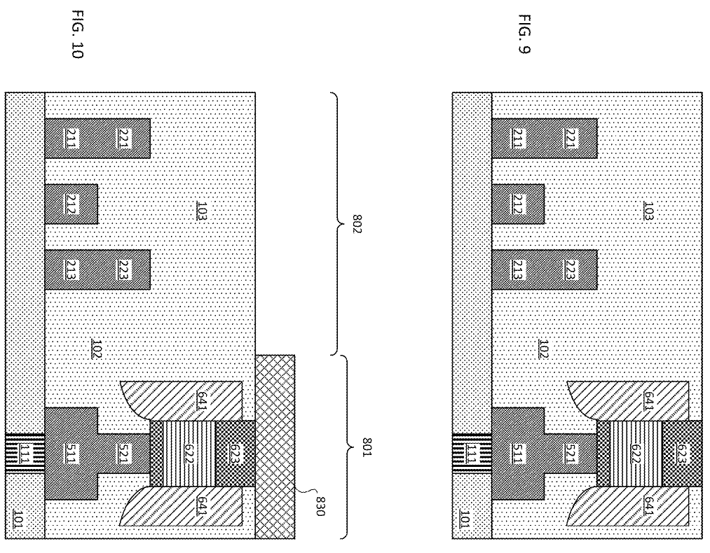

FIG. 8 is a demonstrative illustration of cross-sectional view of the semiconductor structure 10 at a step of manufacturing thereof, following the step illustrated in FIG. 7, according to one embodiment of present invention. More specifically, embodiments of present invention provide patterning the layer of encapsulation material 640 into an encapsulating layer 641 surrounding sidewall surfaces of the MRAM structure 620 and in particular sidewall surfaces of the MTJ pillar 622. In patterning the layer of encapsulation material 640, a directional etch process may be applied that substantially removes horizontal portions of the encapsulation material 640 while leaving vertical portions of the encapsulation material 640 largely un-etched, thereby forming the encapsulating layer 641. The encapsulating layer 641 may cover sidewalls of the MTJ pillar 622, sidewalls of the bottom electrode 621, and at least a portion of sidewalls of the top electrode 623. In one embodiment, because of the encapsulation material 640 filling the gouges 631 and 632 created by the gouging, the encapsulating layer 641 may extend below a bottom surface of the bottom electrode 621. The directional etch process may create recesses 651 and 652 between the top via 221 (a first top via) and the top via 223 (a second top via) of the first metal level 100 and the bottom electrode contact 521. In one embodiment, the directional etch process may also etch away portions of the exposed first and second top vias 221 and 223, making a height of the first and second top vias 221 and 223 slightly lower than that of the bottom electrode contact 521. In other words, the bottom electrode contact 521 may have a height that is higher than a height of the first and second top vias 221 and 223.

FIG. 9 is a demonstrative illustration of cross-sectional view of the semiconductor structure 10 at a step of manufacturing thereof, following the step illustrated in FIG. 8, according to one embodiment of present invention. More specifically, embodiments of present invention provide depositing dielectric material in the recesses 651 and 652 and on top of the exposed first and second top vias 221 and 223 to surround the encapsulating layer 641. Dielectric material may further be deposited on top of and covering the MRAM structure 620 thereby forming a dielectric layer 103. A CMP process may then be applied to planarize a top surface of the dielectric layer 103 until a top surface of the MRAM structure 620, for example a top surface of the top electrode 623 of the MRAM structure 620, is exposed.

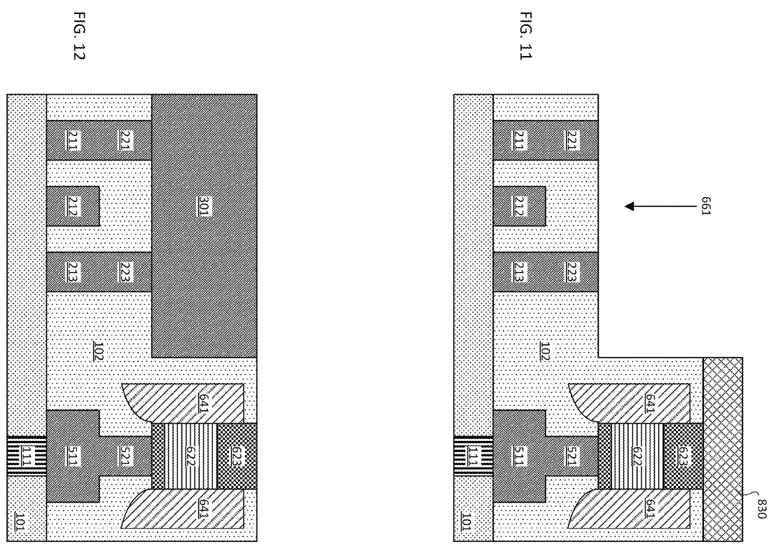

FIG. 10 is a demonstrative illustration of cross-sectional view of the semiconductor structure 10 at a step of manufacturing thereof, following the step illustrated in FIG. 9, according to one embodiment of present invention. More specifically, embodiments of present invention provide forming a mask pattern 830 on top of the dielectric layer 103 to cover the memory area of the MRAM structure 620, such as a first area 801, and leave the logic area of the back-end-of-line (BEOL) regions, such as a second area 802 covering regions of the first and second top vias 221 and 223 and metal lines 211, 212, and 213 of the first metal level 100 largely exposed. The mask pattern 830 may cover the encapsulating layer 641 surrounding the MRAM structure 620 as well. The mask pattern 830 may include a stack of mask layers including at least an organic-planarization (OPL) layer. The mask pattern 830 may be formed through a lithographic patterning process in a process of forming a second metal level as being described below in more details.

FIG. 11 is a demonstrative illustration of cross-sectional view of the semiconductor structure 10 at a step of manufacturing thereof, following the step illustrated in FIG. 10, according to one embodiment of present invention. More specifically, embodiments of present invention provide etching the dielectric layer 103 exposed by the mask pattern 830 selectively, such as through a RIE process, to create one or more recesses such as a recess 661. The recess 661 may be deep enough, at least as deep as a height of the MRAM structure 620, until the first and second top vias 221 and 223 of the first metal level 100 are exposed.

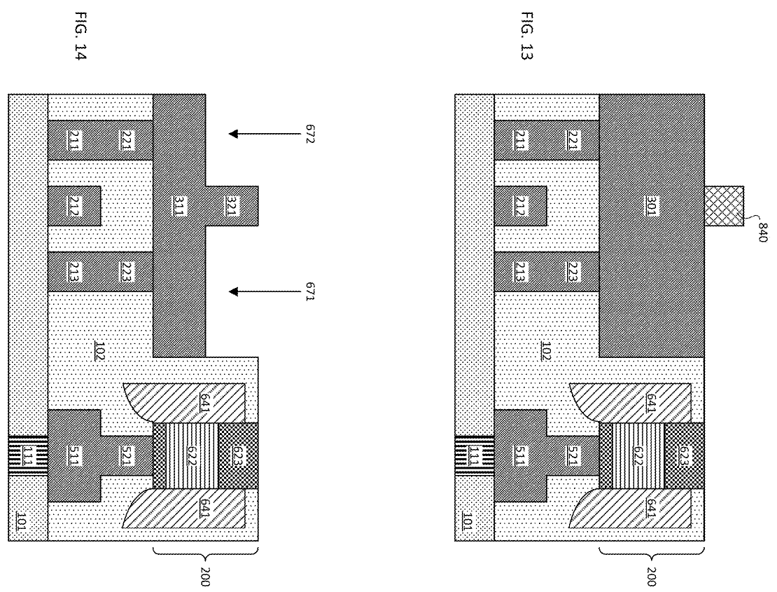

FIG. 12 is a demonstrative illustration of cross-sectional view of the semiconductor structure 10 at a step of manufacturing thereof, following the step illustrated in FIG. 11, according to one embodiment of present invention. More specifically, embodiments of present invention provide filling the one or more recesses, including the recess 661, with a conductive material thereby forming a second set of metal layers including, for example, a metal layer 301 on top of the one or more top vias 221 and 223 of the first metal level 100. Here it is noted that additional metal layers may be formed that are into and out of the drawing. Next, a CMP process may be applied to planarize a top surface of the second set of metal layers such that they become coplanar with the top surface of the MRAM structure 620 such as the top surface of the top electrode 623 of the MRAM structure 620.

FIG. 13 is a demonstrative illustration of cross-sectional view of the semiconductor structure 10 at a step of manufacturing thereof, following the step illustrated in FIG. 12, according to one embodiment of present invention. More specifically, embodiments of present invention provide forming a mask pattern 840 on top of the second set of metal layers 301. The mask pattern 840 may represent a pattern of one or more top vias of a second metal level 200 to be formed from the second set of metal layers. The mask pattern 840 may include a stack of mask layers including at least an OPL layer. The mask pattern 840 may be formed through, for example, a lithographic patterning process.

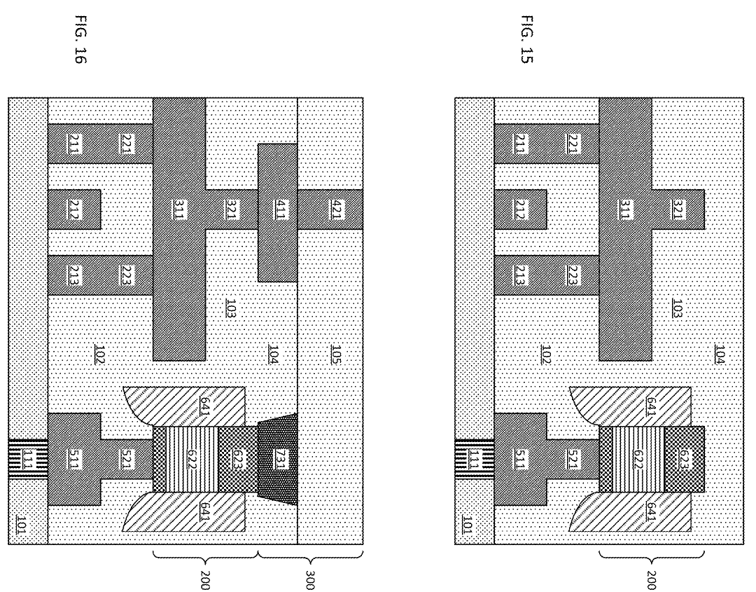

FIG. 14 is a demonstrative illustration of cross-sectional view of the semiconductor structure 10 at a step of manufacturing thereof, following the step illustrated in FIG. 13, according to one embodiment of present invention. More specifically, embodiments of present invention provide forming the second metal level 200 through a subtractive patterning process by selectively etching portions of the second set of metal layers that are not covered or protected by the mask pattern 840. The etching process may thus create recesses such as recesses 671 and 672 thereby forming one or more metal lines such as a metal line 311 of the second metal level 200. The etching process may also create one or more top vias such as a top via 321 of the second metal level 200, from the protected portion of the second set of metal layers, directly on top of the metal line 311. After the etching, the mask pattern 840 may be selectively removed, for example, through an ash process.

In forming the second metal level 200, a subtractive patterning process is applied as being described above. However, embodiments of present invention are not limited in this aspect. For example, a damascene process (single damascene or dual damascene) may be applied to form the second metal level 200 as well. For example, a damascene process may include forming a pattern of openings in the dielectric layer 103 and subsequently filling the openings with one or more conductive materials to form one or more metal lines and one or more top vias in contact with some of the one or more metal lines, thereby forming the second metal level 200.

In one embodiment, a height of the MRAM structure 620 may equal to or less than a height of the second metal level 200. The height of the second metal level 200 may be a combined height of the top via 321 and the metal line 311 of the second metal level 200. In another embodiment, a combined height of the bottom electrode contact 521 and the MRAM structure 620 may equal to a combined height of the top vias 221 and 223 of the first metal level 100, one or more metal lines such as the metal line 311 of the second metal level 200, and one or more top vias such as the top via 321 of the second metal level 200.

FIG. 15 is a demonstrative illustration of cross-sectional view of the semiconductor structure 10 at a step of manufacturing thereof, following the step illustrated in FIG. 14, according to one embodiment of present invention. More specifically, embodiments of present invention provide depositing dielectric material back into the recesses 671 and 672 to form a dielectric layer on top of the metal line 311 surrounding the top via 321. Dielectric material may further be deposited on top of the MRAM structure 620, in particular on top of the top electrode 623 of the MRAM structure 620, and on top of the top via 321 of the second metal level 200 to form a dielectric layer 104. In one embodiment, the dielectric layers 103 and 104 may include low-k dielectric materials such as, for example, SiOC, SiCOH, SiCN, or SiCNO.

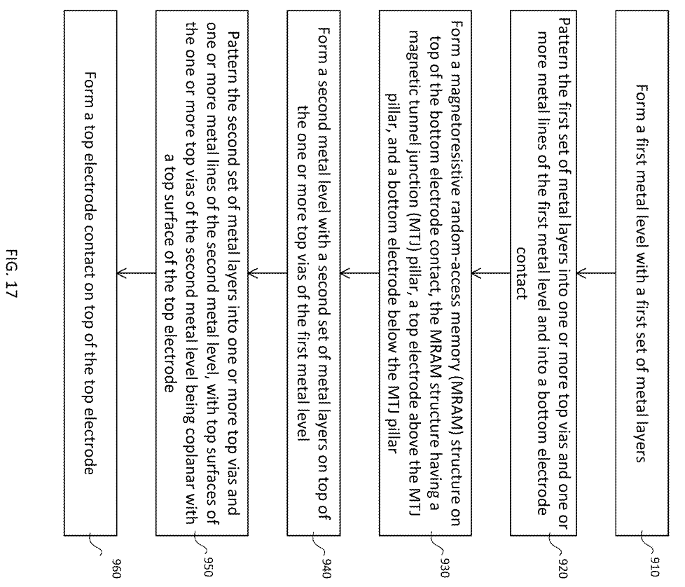

FIG. 16 is a demonstrative illustration of cross-sectional view of the semiconductor structure 10 at a step of manufacturing thereof, following the step illustrated in FIG. 15, according to one embodiment of present invention. More specifically, embodiments of present invention provide performing a damascene process to form a top electrode contact 731 on top of the top electrode 623 of the MRAM structure 620, and one or more metal lines such as a metal line 411 of a third metal level 300. In one embodiment, the top electrode contact 731 may be one of the metal lines of the third metal level 300 as well. One or more top vias such as a top via 421 of the third metal level 300 may also be formed on top of and in contact with the one or more metal lines of the third metal level 300. The one or more top vias of the third metal level 300 may be embedded, or formed to be embedded, in a dielectric layer 105.

FIG. 17 is a demonstrative illustration of a flow-chart of a method of manufacturing a semiconductor structure according to embodiments of present invention. The method includes (910) forming a first metal level with a first set of metal layers; (920) patterning the first set of metal layers into one or more top vias and one or more metal lines of the first metal level and into a bottom electrode contact; (930) forming a magnetoresistive random-access memory (MRAM) structure on top of the bottom electrode contact, the MRAM structure having a magnetic tunnel junction (MTJ) pillar, a top electrode above the MTJ pillar, and a bottom electrode below the MTJ pillar; (940) forming a second metal level with a second set of metal layers on top of the one or more top vias of the first metal level; (950) patterning the second set of metal layers into one or more top vias and one or more metal lines of the second metal level, with top surfaces of the one or more top vias of the second metal level being coplanar with a top surface of the top electrode; and (960) forming a top electrode contact on top of the top electrode.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a magnetoresistive random-access memory (MRAM) structure having a magnetic tunnel junction (MTJ) pillar; a top electrode at a top surface of the MTJ pillar; and a bottom electrode at a bottom surface of the MTJ pillar;
a bottom electrode contact in contact with a bottom surface of the bottom electrode; and
a back-end-of-line interconnect structure having at least a first and a second metal levels, each metal level including one or more metal lines and one or more top vias, the one or more top vias of the first metal level connecting the one or more metal lines of the first metal level to the one or more metal lines of the second metal level,
wherein a top surface of the top electrode is coplanar with top surfaces of the one or more top vias of the second metal level, and a bottom surface of the bottom electrode contact is coplanar with bottom surfaces of the one or more top vias of the first metal level.

2. The semiconductor structure of claim 1, wherein a bottom surface of the bottom electrode is coplanar with bottom surfaces of the one or more metal lines of the second metal level.

3. The semiconductor structure of claim 1, wherein the bottom electrode contact is directly on top of a metal line of the first metal level and has a width that is narrower than a width of the metal line of the first metal level.

4. The semiconductor structure of claim 3, wherein the MRAM structure and the interconnect structure are formed on top of a dielectric layer, and a conductive via embedded in the dielectric layer connects the MRAM structure, via the metal line of the first metal level, to an active device underneath the dielectric layer.

5. The semiconductor structure of claim 1, further comprising an encapsulating layer surrounding sidewalls of the MTJ pillar, wherein the encapsulating layer extends below a bottom surface of the bottom electrode to horizontally surround at least a portion of the bottom electrode contact.

6. The semiconductor structure of claim 1, further comprising a third metal level having one or more metal lines, wherein one of the one or more metal lines of the third metal level is a top electrode contact in contact with a top surface of the top electrode of the MRAM structure.

7. The semiconductor structure of claim 1, wherein the bottom electrode contact has a height that is higher than a height of the one or more top vias of the first metal level.

8. The semiconductor structure of claim 1, wherein a combined height of the bottom electrode contact and the MRAM structure equals to a combined height of the one or more top vias of the first metal level, the one or more metal lines of the second metal level, and the one or more top vias of the second metal level.

9. A method of forming a semiconductor structure comprising:
forming a first metal level with a first set of metal layers;
patterning the first set of metal layers into one or more top vias and one or more metal lines of the first metal level and into a bottom electrode contact;
forming a magnetoresistive random-access memory (MRAM) structure on top of the bottom electrode contact, the MRAM structure having a magnetic tunnel junction (MTJ) pillar, a top electrode above the MTJ pillar, and a bottom electrode below the MTJ pillar;
forming a second metal level with a second set of metal layers on top of the one or more top vias of the first metal level;
patterning the second set of metal layers into one or more top vias and one or more metal lines of the second metal level, with top surfaces of the one or more top vias of the second metal level being coplanar with a top surface of the top electrode; and
forming a top electrode contact on top of the top electrode.

10. The method of claim 9, further comprising:
embedding the one or more top vias of the first metal level in a dielectric layer;
depositing a bottom electrode layer on top of the one or more top vias of the first metal level and the dielectric layer;
depositing an MTJ stack on top of the bottom electrode layer; and
depositing a top electrode layer on top of the MTJ stack.

11. The method of claim 10, further comprising patterning the top electrode layer, the MTJ stack, and the bottom electrode layer into the top electrode, the MTJ pillar, and the bottom electrode in a selective etch process, the selective etch process creates gouges in the dielectric layer between the one or more top vias of the first metal level.

12. The method of claim 11, further comprising forming an encapsulating layer surrounding sidewalls of the MTJ pillar, the encapsulating layer having a material different from that of the dielectric layer.

13. The method of claim 9, wherein patterning the first set of metal layers into the bottom electrode contact comprises etching one of the metal layers into a bottom electrode contact on top of a metal line of the first metal level, the bottom electrode contact having a width narrower than a width of the metal line of the first metal level.

14. The method of claim 9, wherein patterning the first set of metal layers comprises etching the first set of metal layers in a subtractive patterning process.

15. The method of claim 9, wherein forming the top electrode contact on top of the top electrode comprises forming one or more metal lines of a third metal level on top of the one or more top vias of the second metal level and on top of the top electrode of the MRAM structure.

16. A semiconductor structure comprising:
a magnetoresistive random-access memory (MRAM) structure having a magnetic tunnel junction (MTJ) pillar; a top electrode on top of the MTJ pillar; and a bottom electrode underneath the MTJ pillar;
a bottom electrode contact in contact with a bottom surface of the bottom electrode; and
a back-end-of-line interconnect structure having a first and a second metal levels, each metal level including one or more top vias on top of one or more metal lines,
wherein a top surface of the top electrode is coplanar with top surfaces of the one or more top vias of the second metal level, and a bottom surface of the bottom electrode contact is coplanar with bottom surfaces of the one or more top vias of the first metal level.

17. The semiconductor structure of claim 16, wherein a bottom surface of the bottom electrode is coplanar with bottom surfaces of the one or more metal lines of the second metal level.

18. The semiconductor structure of claim 16, wherein the bottom electrode contact is directly on top of a metal line of the first metal level, the bottom electrode contact and the metal line of the first metal level have different widths.

19. The semiconductor structure of claim 16, further comprising an encapsulating layer surrounding sidewalls of the bottom electrode; sidewalls of the MTJ pillar, and at least a portion of sidewalls of the top electrode.

20. The semiconductor structure of claim 16, wherein a height of the MRAM structure is equal to or less than a height of the second metal level.
